(19) United States
(12) Patent Application Publication
(10) Pub. No.: US 2002/0146885 A1
(43) Pub. Date: Oct. 10, 2002

(54) Method of fabricating a nitride read only memory cell

(76) Inventor: Chia-Hsing Chen, Hsin-Chu City (TW)

Correspondence Address: NAIPO (NORTH AMERICA INTERNATIONAL PATENT OFFICE), P.O. BOX 506, MERRIFIELD, VA, 22116, US

(21) Appl. No.: 10/063,246

(22) Filed: Apr. 3, 2002

(30) Foreign Application Priority Data
Apr. 4, 2001 (TW) 090108196

(51) Int. Cl. H01L 21/336

(52) U.S. Cl. 438/288

(57) ABSTRACT

A substrate comprising a memory array region and a periphery circuit region is provided. An ONO dielectric layer is formed on the total surface of the substrate in both the memory array region and the periphery circuit region. Not removing the ONO dielectric layer, an ion implantation process is performed to form a plurality of buried bit lines within the substrate. Finally, a plurality of word lines, approximately perpendicular to the buried bit lines, is formed on the surface of the ONO dielectric layer in the memory array region. Since the ONO dielectric layer is not etched away before the implantation process, the diffusion profile of the buried lines is not altered.

### BACKGROUND OF INVENTION

1. Field of the Invention

The present invention relates to a method of fabricating a nitride read only memory (NROM) cell, and more particularly, to a simplified method of fabricating a NROM cell without affecting a diffusion profile of a buried bit line.

2. Description of the Prior Art

Nitride read only memory (NROM), comprising a plurality of memory cells, is used to store data. Each memory cell is composed of a MOS transistor and a silicon nitride layer. Since the silicon nitride layer has a high density, hot electrons tunnel through the MOS transistor to become trapped in the silicon nitride layer, thus achieving information storage.

Please refer to FIG. 1 to FIG. 4. FIG. 1 to FIG. 4 are schematic diagrams of a prior art of fabricating a NROM cell. As shown in FIG. 1, the NROM cell is formed on a silicon substrate 12. The silicon substrate 12 is a P-type silicon substrate and comprises a memory array region for storing electrons and a periphery circuit region for controlling the logic circuits. A first step of the prior method is to perform a conventional oxide-nitride-oxide (ONO) process to form an ONO dielectric layer 19 on the surface of the silicon substrate 12. The ONO dielectric layer 19 comprises a bottom oxide layer 14, a silicon nitride layer 16 and a top oxide layer 18. Following this, a photoresist layer 20 is formed on the ONO layer 19 followed by a photolithographic and etching process to define patterns of a bit line in the photoresist layer 20.

As shown in FIG. 2, using the patterned photoresist layer 20 as a mask, a dry etching process is performed to remove the top oxide layer 18 and the silicon nitride layer 16. An ion implantation process with a direction 22 is then performed to form a plurality of doped areas 24 within the silicon substrate 12. The doped areas 24 function as a bit line or a buried drain. Thereafter, the photoresist layer 20 is completely removed.

As shown in FIG. 3, a thermal oxidation process is performed to form a field oxide layer 26 on the surface of the bit line 24 to isolate two silicon nitride layers 16 from each other. Finally, as shown in FIG. 4, a doped polysilicon layer 28 is deposited as a word line.

Some disadvantages exist according to the prior art:(1)An etching process on the ONO dielectric layer 19 is required to remove both the top oxide layer 18 and the silicon nitride layer 16; and(2)Following the ion implantation process 22 for forming the buried drain (bit line) 24, a thermal oxidation process is required to form the field oxide layer 26 between two silicon nitride layers 16. However, the profile of the buried drain (bit line) 24 can easily change during the thermal oxidation process.

### SUMMARY OF INVENTION

It is therefore an objective of the present invention to provide a method of fabricating a NROM cell to simplify the fabricating processes as well as to increase the production yield.

It is another objective of the present invention to provide a method of fabricating a NROM cell to prevent changes in the diffusion profile of a buried drain (bit line).

The present invention comprises the following steps-of:(1)providing a substrate comprising a memory array region and a periphery circuit region;(2)forming a oxide-nitride-oxide (ONO) layer to cover both the memory array region and the periphery circuit region, the ONO layer comprising a bottom oxide layer, a silicon nitride layer and a top oxide layer;(3)forming a plurality of columns of bit line masks on the ONO layer in the memory array region;(4)performing an ion implantation process to form a plurality of bit lines within the substrate not covered by the bit line masks, the ONO layer over the bit lines being preserved during the ion implantation process;(5) removing the bit line masks; and(6)forming a plurality of rows of word lines on the ONO layer, the word lines being approximately perpendicular to the bit lines.

During a programming process of the NROM cell, hot electrons transfer from the substrate, pass a channel between two buried drains, and at last inject into the silicon nitride layer of the ONO dielectric layer. The transferring range of each hot electron depends on it's energy. As a result, a plurality of independent concentration distribution regions of the hot electrons is formed in the silicon nitride layer, and each concentration distribution region positions over each buried drain to store the hot electrons. Hence, it is an advantage of the present invention that an etching process on the ONO layer is not necessary.

These and other objectives of the present invention will no doubt become obvious to those of ordinary skill in the art after reading the following detailed description of the preferred embodiment, which is illustrated in the various figures and drawings.

### BRIEF DESCRIPTION OF DRAWINGS

FIG. 1 to FIG. 4 are schematic diagrams of a prior art of fabricating a NROM cell; and FIG. 5 to FIG. 8 are schematic diagrams of a method of fabricating a NROM cell according to the present invention.

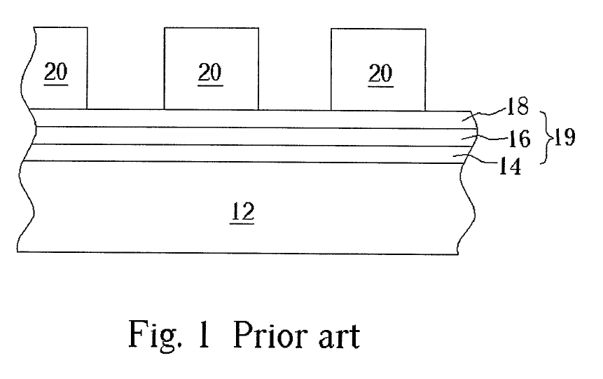

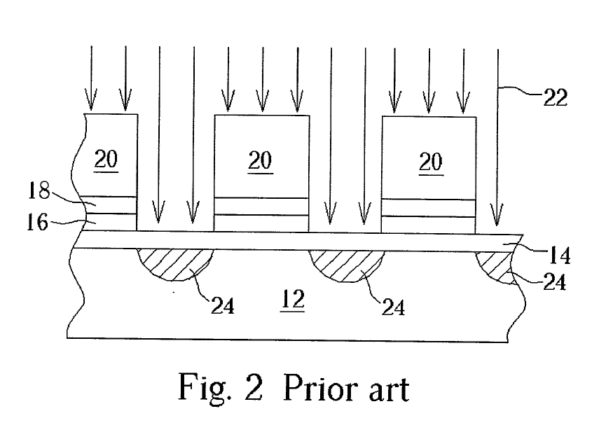

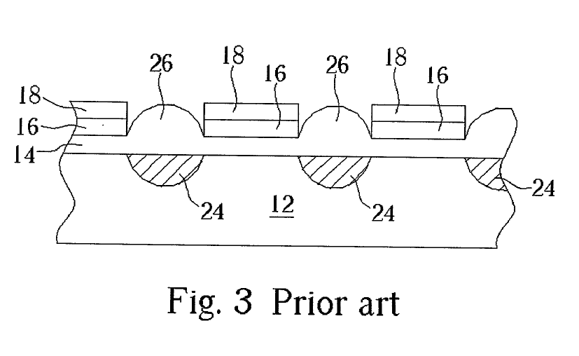

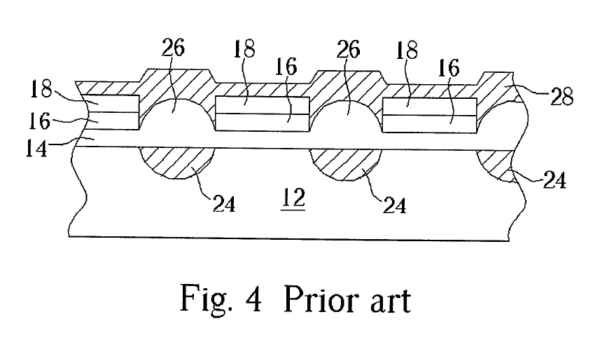

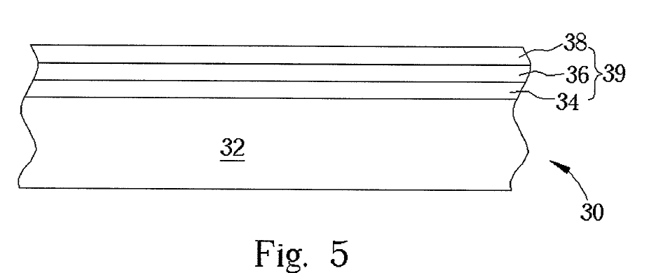

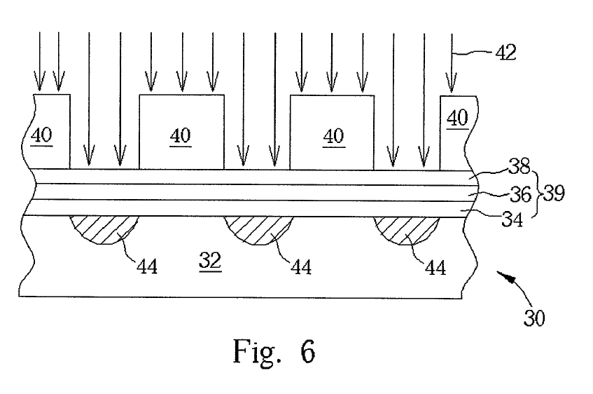

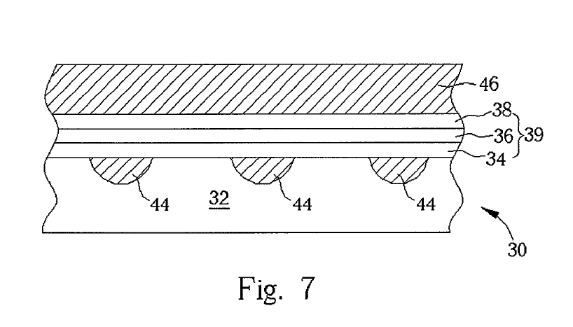

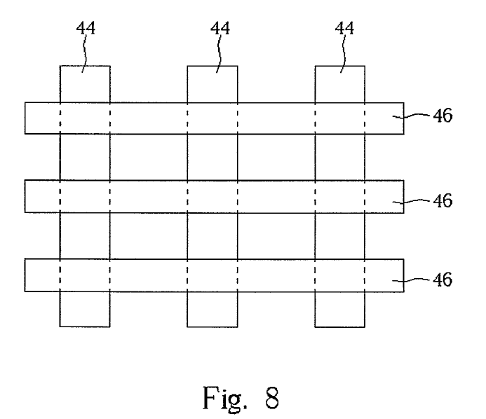

### DETAILED DESCRIPTION

Please refer to FIG. 5 to FIG. 8. FIG. 5 to FIG. 8 are schematic diagrams of a method of fabricating a NROM cell according to the present invention. As shown in FIG. 5, the NROM cell is formed on a substrate 32 of a semiconductor wafer 30. The substrate 32 comprises a memory array region and a periphery circuit region. In a better embodiment of the present invention, the substrate 32 is a P-type silicon substrate. Alternatively, the substrate 32 can be a silicon-on-insulator (SOI) substrate. To specify the main features of the present invention, only a cross-sectional view of the NROM cell within the memory array region is shown in FIG. 5 to FIG. 8.

As shown in FIG. 5, an ONO dielectric layer 39 with a thickness of 150 to 250 angstroms is formed on the surface of the substrate 32. The ONO dielectric layer 39 is composed of a bottom oxide layer 34 with a thickness between 20 and 150 angstroms, a silicon nitride layer 36 with a thickness between 20 and 150 angstroms, and a top oxide layer 38 with a thickness between 30 and 150 angstroms.

As shown in FIG. 6, a photoresist layer 40 is formed on the ONO layer 39 followed by a photolithographic and etching process to define patterns of a bit line in the photoresist layer 40. A plurality of columns of bit line masks is thus formed using the patterned photoresist layer 40. Then, an ion implantation process with a direction 42 is performed to implant arsenic (As) ions or the other N-type dopants into the substrate 32 not covered by the photoresist layer 40. Thus, a plurality of N-doped areas 44 is formed within the substrate 32 as a bit line of the memory cell. In the ion implantation process 42, the implant dosage of the As ions is approximately 1E15 to 1E16 atoms/cm₂ while the implant energy of the As ions is approximately 20 to 80 KeV. A preferred implant energy for the As ions is suggested as 50 KeV. Subsequently, following the photoresist layer 40 is removed, a rapid thermal annealing process is performed at a temperature of 800° C. to 1000° C. to activate dopants in the substrate 32.

As shown in FIG. 7, a doped polysilicon layer 46 is deposited on the surface of the semiconductor wafer 30 as a word line. After the deposition process, a plurality of rows of word lines 46 is formed on the semiconductor wafer 30 approximately perpendicular to the doped area 44 (bit lines), as shown in FIG. 8.

In other embodiments of the method according to the present invention, prior to forming the bit line masks 40 the method further comprises: (1) forming a mask (not shown) on the ONO dielectric layer 39 in the memory array region; (2) performing an ion implantation process to adjust dopant concentration of the substrate 32 not covered by the mask; and (3) removing the mask. As a result of these three steps, the threshold voltage in the periphery circuit region is adjusted.

Since each hot electron ejected from the substrate 32 into the silicon nitride layer 36 has a transferring range dependant on the electron's energy, a plurality of independent concentration distribution regions of the hot electrons is thus formed in the silicon nitride layer 36, and each concentration distribution region positions over each bit line 44 to store the hot electrons. As a result, the present invention removes the step of an etching process on the ONO layer, as taught by the prior art. In addition, problems resulting from forming an insulating layer on the bit line 44 are completely prevented.

In contrast to the prior art of forming a NROM cell, the method of the present invention performs an ion implantation process 42 directly on the surface of the ONO dielectric layer 39 to form the doped area (bit line) 44. Hence, the steps taught by the prior art including an etching process of the ONO dielectric layer 19 and covering of the field oxide layer 26 to insulate two ONO dielectric layers 19 from each other are completely removed. In addition to simplify the fabrication process, the present invention further prevents dopants in the bit line from diffusing into the substrate and current leakage problems, thus improving production yields.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method of fabricating a nitride read only memory (NROM) cell, the method comprising:
providing a substrate comprising a memory array region and a periphery circuit region;
forming a oxide-nitride-oxide (ONO) layer to cover both the memory array region and the periphery circuit region;
forming a plurality of columns of bit line masks on the ONO layer of the memory array region;
performing a first ion implantation process to form a plurality of bit lines within the substrate not covered by the bit line masks, the ONO layer over the bit lines being preserved during the first ion implantation process;
removing the bit line masks; and
forming a plurality of rows of word lines on the ONO layer, the word lines being approximately perpendicular to the bit lines.

2. The method of claim 1 wherein before forming the bit line masks the method further comprises:
forming at least one mask on the ONO layer of the memory array region;
performing a second ion implantation process to adjust a dopant concentration of the substrate not covered by the mask; and
removing the mask.

3. The method of claim 1 wherein the ONO layer comprises a bottom oxide layer, a silicon nitride layer and a top oxide layer.

4. The method of claim 1 wherein the ONO layer is 150 to 250 angstroms (Å) thick, the bottom oxide layer is 20 to 150 Å thick, the silicon nitride layer is 20 to 150 Å thick, and the top oxide layer is 30 to 150 Å thick.

5. The method of claim 1 wherein after performing the first ion implantation process, a rapid thermal annealing (RTA) process is used to activate dopants implanted within the substrate.

6. The method of claim 1 wherein the bit line masks comprise photoresist materials.

7. The method of claim 1 wherein the substrate is a silicon-on-insulator (SOI) substrate.

8. The method of claim 1 wherein the substrate is a silicon substrate.
